(19) United States
(12) Patent Application Publication
(10) Pub. No.: US 2004/0017698 A1
(43) Pub. Date: Jan. 29, 2004

(54) Refined gate coupled noise compensation for open-drain output from semiconductor device

(75) Inventor: Brian W. Huber, Allen, TX (US)

Correspondence Address: Hugh R. Kress, 2400 Bank One Center, 910 Travis Street, Houston, TX, 77002, US

(73) Assignee: Micron Technology, Inc., Boise, ID

(21) Appl. No.: 10/205,372

(22) Filed: Jul. 25, 2002

(51) Int. Cl. G11C 7/00

(52) U.S. Cl. 365/189.11

(57) ABSTRACT

An open-drain output circuit for a semiconductor device is provided with compensation circuitry for minimizing fluctuations in a regulated gate voltage applied to the gate of an open-drain output transistor. In one embodiment, a compensation voltage is derived from an input signal to the output circuit and applied to one terminal of a capacitor. A second terminal of the capacitor is coupled to the gate of the open-drain output transistor. The compensation circuit comprises at least one pull-up transistor and at least one pull-down transistor coupled to a first terminal of the capacitance. The capacitance couples the compensation voltage to the gate of the output transistor, thereby compensating for capacitive coupling noise induced in constant-voltage gate signal applied to the gate of the output transistor upon assertion of the input signal to the output circuit.

### FIELD OF THE INVENTION

This invention relates generally to semiconductor devices, and more particularly relates to an open-drain output circuit for a semiconductor device.

### BACKGROUND OF THE INVENTION

Integrated circuits typically include a number of input/output pins which are used for communication with additional circuitry. For example, an integrated memory device such as a dynamic random access memory (DRAM) includes both control inputs for receiving memory operation control signals, and data pins for bi-directional data communication with an external system or processor.

The data transmission rate of modern integrated circuits is primarily limited by internal circuitry operating speeds. That is, communication networks have been developed which can transmit signals between circuitry at a rate that is faster than the capacity of many integrated circuits. To address the need for faster circuits, a group of integrated circuits can be combined on a common bus. In this configuration, each integrated circuit operates in a coordinated manner with the other integrated circuits to share data which is transmitted at a high speed. For example, a group of memory devices, such as DRAMs, static RAMs, or read only memories (ROM), can be connected to a common data bus. The data rate of the bus may be substantially faster than the feasible operating speed of the individual memories. Each memory, therefore, is operated so that while one memory is processing received data, another memory is receiving new data. By providing an appropriate number of memory devices and an efficient control system, very high speed data transmissions can be achieved.

As the transmission rate of the data communication signals continues to increase, new circuitry and methods are needed to accurately transmit data from each integrated circuit. One proposed solution is a bus driver described in U.S. Pat. No. 5,254,883. This bus driver circuit uses parallel open-drain output transistors. The output transistors are fabricated in different sizes and selectively activated to control the bus current. This technique requires a relatively large number of output transistors to implement.

In one type of open-drain output circuit, a substantially constant reference voltage is applied to the gate of the open-drain output transistor, as will be discussed hereinbelow with reference to FIG. 1. Those of ordinary skill in the art will appreciate that it is possible for certain electrical coupling effects during operation to adversely affect the output transistor's gate voltage. Such “noise” in the gate voltage can have undesirable consequences with respect to the quality of the output signal appearing on the output pad driven by the output circuit.

Thus, it is believed that it would be desirable to provide an output circuit arrangement which compensates for coupling and other effects that can lead to noise in the output circuit.

### SUMMARY OF THE INVENTION

The present invention relates to an apparatus and corresponding method for compensating for noise in an open-drain output circuit for a semiconductor device.

In one embodiment of the invention, capacitive coupling effects leading to slight fluctuations in the regulated constant gate voltage applied to an open-drain output transistor are compensated by means of a compensation voltage coupled to the gate of the output transistor by a capacitor. The compensation voltage is derived from the input to the output circuit by at least one pull-up transistor and at least one pull-down transistor tied to a compensation voltage node.

In another embodiment of the invention, the effective transistor sizes of the pull-up and pull-down transistors can be corrected to account for transistor strength, power supply variation, and temperature effects. This is accomplished in one embodiment by providing a plurality of additional pull-up and pull down transistors which are selectively activated based upon a correction bit code.

### BRIEF DESCRIPTION OF THE DRAWINGS

The foregoing and other features and aspects of the present invention will be best understood with reference to the following detailed description of a specific embodiment of the invention, when read in conjunction with the accompanying drawings, wherein:

FIG. 1 is a simplified schematic diagram of a prior art open-drain output circuit;

FIGS. 2a and 2b are plots of the pad voltage and output transistor gate voltage, respectively, during operation of the open-drain output circuit from FIG. 1;

FIG. 3 is a simplified schematic diagram of an alternative prior art open-drain output circuit;

FIG. 4 is a simplified schematic diagram of an open-drain output circuit in accordance with one embodiment of the invention;

FIGS. 5a-5c are waveforms showing the compensation signals, the charge transferred, and the compensated output transistor gate voltage in the output circuit of FIG. 4;

FIG. 6 is a simplified schematic diagram of an open drain output circuit in accordance with an alternative embodiment of the invention; and

FIGS. 7a and 7b are simplified schematic diagrams of correction code decoding circuitry for the embodiment of FIG. 6.

### DETAILED DESCRIPTION OF SPECIFIC EMBODIMENTS OF THE INVENTION

In the disclosure that follows, in the interest of clarity, not all features of actual implementations are described. It will of course be appreciated that in the development of any such actual implementation, as in any such project, numerous engineering and programming decisions must be made to achieve the developers' specific goals and subgoals (e.g., compliance with system and technical constraints), which will vary from one implementation to another. Moreover, attention will necessarily be paid to proper engineering practices for the environment in question. It will be appreciated that such a development effort might be complex and time-consuming, but would nevertheless be a routine undertaking for those of ordinary skill in the relevant fields.

Furthermore, for the purposes of the present disclosure, the terms “comprise” and “comprising” shall be interpreted in an inclusive, non-limiting sense, recognizing that an element or method step said to “comprise” one or more specific components may include additional components. Also, it is to be understood that the terms “coupled” and “coupled to” as used to describe the interrelationship of two recited elements shall be interpreted so as to not exclude the possibility of intermediate elements disposed between the recited elements. That is, a first element may be “coupled to” a second element indirectly by means of one or more additional elements (for example (without limitation), a resistor, a transistor, or an inverter, and the terms “coupled” and “coupled to” shall necessarily not be interpreted as either implying or excluding being “coupled directly” or “coupled directly to.” Such a distinction is especially relevant in situations where a first element is “selectively” coupled to a second element, for example through the source-to-drain path of a transistor, or where a logic signal passes through an even number of inverters.

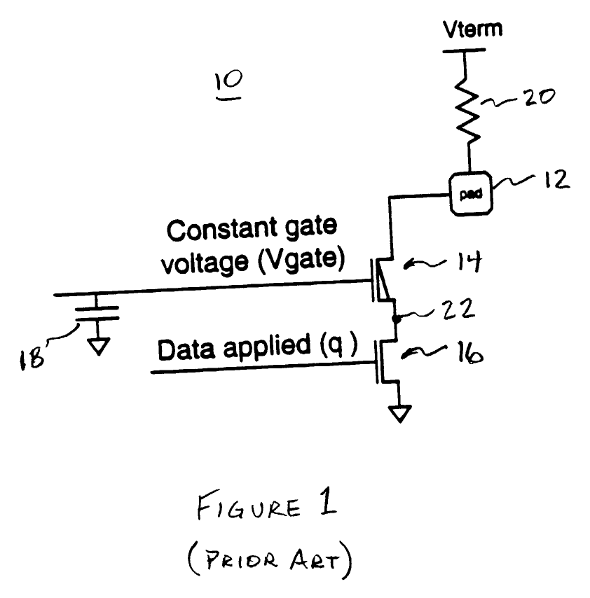

Referring to FIG. 1, there is shown a prior art open-drain output circuit 10 for driving an output signal on an output pad 12 of a semiconductor device. As shown in FIG. 1, output circuit 10 comprises an N-channel output field-effect transistor (FET) 14 and a second N-channel FET 16 coupled in series between output pad 12 and ground potential. A substantially constant gate potential V_{gate} is maintained on the gate of output transistor 14, and a capacitance 18 is coupled between the gate of transistor 14 and ground potential. Gate potential V_{gate} is preferably generated by a voltage regulator circuit (not shown in FIG. 1) in accordance with conventional practice in the art. The term “substantially constant” is used herein in recognition of the fact that depending upon the particular implementation of a voltage regulator circuit, the V_{gate} voltage may be susceptible to minor fluctuations due, for example, to capacitive coupling effects, noise, processing variation, and so on, as will be hereinafter described in greater detail. Finally, output circuit 10 further comprises a termination resistance 40 coupled between output pad 12 and a termination voltage Vₜₑᵣₘ.

Operation of output circuit 10 occurs as follows: When input signal q is asserted to a logical high level, FET 16 turns on, providing a current path between an intermediate node 22 and ground potential. Thus, a current path from Vₜₑᵣₘ to ground is established, and the voltage on output pad 12 is pulled to ground. On the other hand, when input signal q is at a low logical level, FET 16 turns off, such that no current path is present through transistor 14. Under these circumstances, the voltage on output pad 12 is maintained at a positive voltage of Vₜₑᵣₘ less the voltage drop across resistor 20.

Those of ordinary skill in the art will appreciate that when input signal q is asserted to a high logical voltage level) turning transistor 16 on, coupling effects through output transistor 14 can cause the constant gate voltage V_{gate} to be pulled down slightly from its steady-state value. Such a fluctuation in the otherwise constant V_{gate} voltage adversely affects conduction through FET 14, which in turn adversely impacts the signal driven on pad 12.

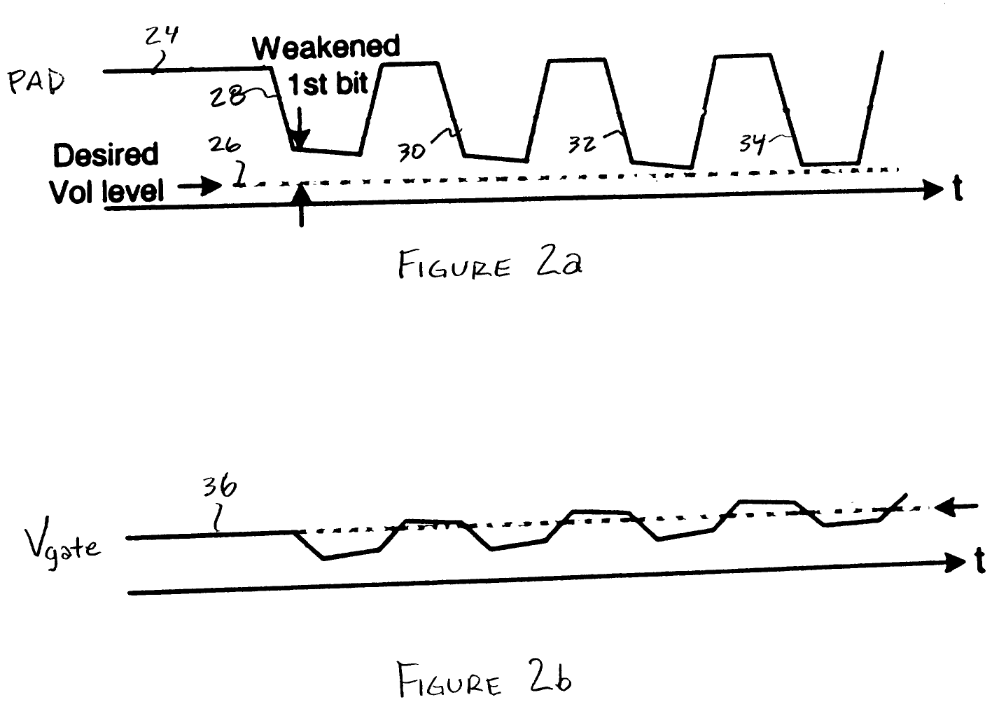

In particular, as depicted in FIG. 2a, it is apparent that a slight downward fluctuation of the V_{gate} voltage can prevent the pad voltage from being pulled to a desired low voltage. In FIG. 2a, waveform 24 represents the signal driven on pad 12 and a dashed line 26 represents the desired low voltage level for pad 12. As shown in FIG. 2a, a first falling edge 28 in pad voltage 24 fails to reach the desired low voltage 26. Subsequent falling edges 30, 32, and 34 get progressively closer to desired level 26 due to the operation of voltage regulating circuitry (not shown in FIG. 1) as is conventionally provided in semiconductor devices when substantially constant voltages such as V_{gate} are required.

Waveform 36 in FIG. 2b depicts the fluctuations in the V_{gate} voltage as a result of the above-described coupling effects.

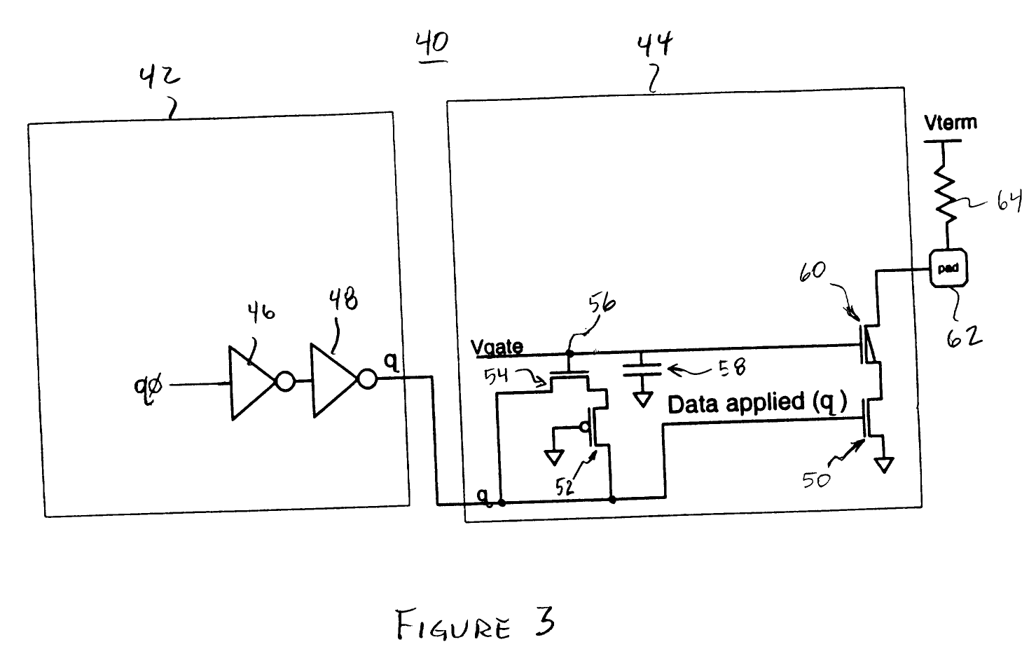

Various approaches have been proposed in the prior art for compensating for noise in the otherwise constant V_{gate} voltage of an open-drain output circuit. FIG. 3 is a simplified schematic diagram depicting one such approach. FIG. 3 shows an output driver circuit 40 comprising a “pre-driver” circuit 42 and an output circuit 44. Pre-driver circuit 42 comprises, at its essence, a pair of serially-connected inverters 46 and 48 to condition input signal q0 to a level appropriate to output circuit 44. Output circuit 44 receives the input signal q at several nodes, including the gate of a first N-channel FET 50, one terminal of a P-channel FET 52, and one terminal of a capacitor 54. As shown in FIG. 3, capacitor 54 is preferably comprised of a capacitor-configured FET having one terminal coupled directly to input signal q, another terminal coupled to input signal q via P-channel FET 52, and a gate terminal coupled to the V_{gate} constant-current supply node designated with reference numeral 56 in FIG. 3. The gate of P-channel FET 52 is coupled to ground potential, keeping FET 52 turned on.

A capacitance 58 is also coupled to V_{gate} supply node 56, similarly to capacitance 18 in the prior art embodiment of FIG. 1. V_{gate} supply node 56 is applied to the gate terminal of an output transistor 60. Transistor 50 is serially-connected between one terminal of transistor 60 and ground. The other terminal of transistor 60 is coupled to an output pad 62. As in the embodiment of FIG. 1, output pad 60 is supplied with a termination voltage Vₜₑᵣₘ via a termination resistance 64.

Those of ordinary skill in the art will appreciate that the configuration depicted in FIG. 3 results in a compensation for the potential for coupling noise in the V_{gate} voltage by marginally boosting the potential on node 56, through capacitance 54, upon assertion of input signal q.

Since the prior art approach for noise compensation represented in FIG. 3 relies upon the input signal q directly, the effects are necessarily limited. It is believed that the present invention offers significant advantages, as described below.

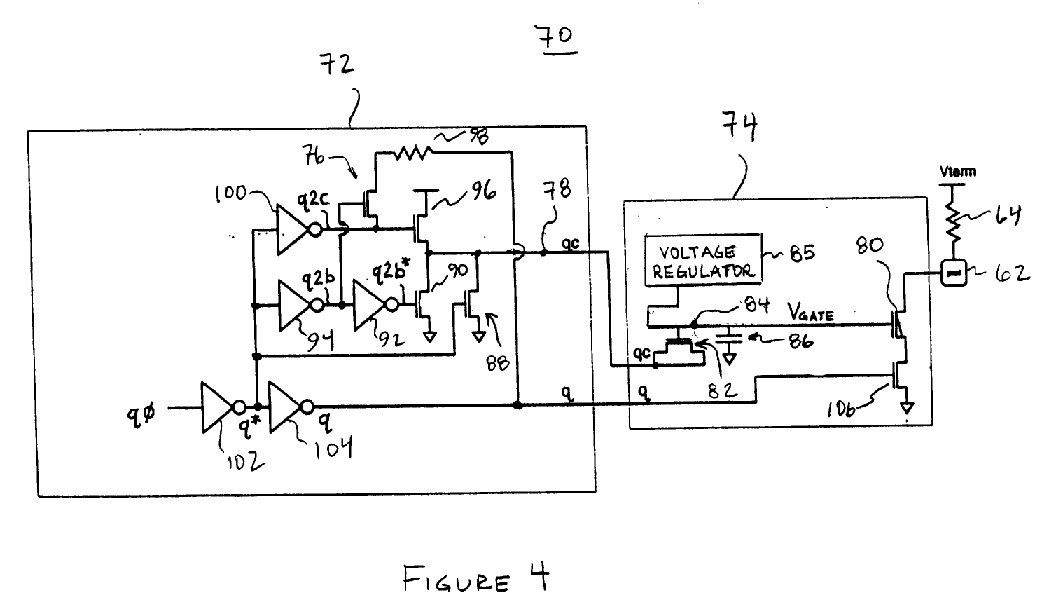

Turning to FIG. 4, there is shown an open-drain output circuit 70 which, like the embodiment of FIG. 3 comprises a “pre-driver” circuit 72 and an output circuit 74.

As a preliminary matter, those of ordinary skill in the art will appreciate that N-channel FET 96 would have the appropriate electrostatic discharge (ESD) protection. The voltage on compensation node qc (reference numeral 78) compensates the upper gate voltage of output driver FET 80 through a capacitance 82. In particular, as will become apparent, capacitance 82 serves to couple the voltage on qc compensation node 78 to V_{gate} node 84. In one embodiment, capacitance 82 is implemented as an N-channel FET 82 configured as a capacitor, i.e., a FET having its source and drain terminals serving as one “plate” or terminal of a capacitor and coupled to qc compensation node 78, and having its gate terminal serving as another “plate” or terminal of the capacitor and coupled to V_{gate} node 84, which receives a regulated constant voltage signal V_{gate} from a voltage regulator circuit 85. A wide variety of voltage regulators for generating substantially constant voltage signals are known in the prior art, and it would be a matter of routine engineering to one of ordinary skill in the art to implement a voltage regulator circuit 85 suitable for the purposes of practicing the invention. The details of implementation of voltage regulator 85 in the embodiment of FIG. 4 are not believed to be of particular relevance for the purposes of understanding and practicing the present invention, and hence such details will not be further discussed herein.

V_{gate} node 84 is coupled to the gate terminal of output transistor 80, likewise in accordance with previous embodiments. A capacitance 86 is also coupled between the gate of output transistor 80 (and V_{gate} node 84) and ground potential, as in the embodiments of FIGS. 1 and 3.

Those of ordinary skill in the art having the benefit of the present disclosure will readily appreciate the details of operation of output circuit 70. N-channel transistor 88 provides an early phase pull-down on compensation node qc 78, and accordingly can be considered a “pull-down” transistor with respect to compensation node qc 78. N-channel transistor 90 provides a delayed-phase pull-down on node qc 78, the delay being attributable to the switching delays of inverters 92 and 94; accordingly, transistor 90 can also be considered a “pull-down” transistor with respect to node qc 78. Inverters 92 and 94 (as well as other inverters in the embodiment of FIG. 4) may be implemented in any conventional manner. As can be observed in FIG. 4, the output of inverter 94 tracks the input signal q0 (delayed by the switching times of inverters 102 and 94), whereas the output of inverter 92 is the complement q2b* of input signal q0 (delayed 11 by the switching times of inverters 102, 94, and 92. Those of ordinary skill in the art will readily appreciate how the relative sizings of transistors 88 and 90 can be specified to tune the pull-down characteristics on node qc 78 to desired parameters.

N-channel FET 96 provides pull-up for compensation node qc 78, and thus can be considered and referred to as a “pull-up” transistor with respect to qc node 78. Relatively, the gate of transistor 106 loads signal q much more than the gate of transistor 96 loads signal q2c. This allows q2c to lead q although both signals are just two inverter delays after input signal q0. Transistor 76 and a resistance 98 comprise a selective, resistive coupling between signal q and the output of an inverter 100 which induces q2c to track the voltage level of signal q (plus some offset), thereby smoothing the pull-up of compensation node qc 78. Inverter 104 is provided to supply the signal q to resistance 98 and to the gate of input transistor 106, whose operation is analogous to transistor 16 in the embodiment of FIG. 1 and transistor 50 in the embodiment of FIG. 3. (In FIG. 4, output pad 62, termination resistance 64, and termination voltage Vₜₑᵣₘ have retained the same designations as in the prior art embodiment of FIG. 3.) That is, the source-to-drain path of transistor 106 selectively couples one terminal of output transistor 80 to ground, as controlled at its gate by input signal q after having passed through inverters 102 and 104.

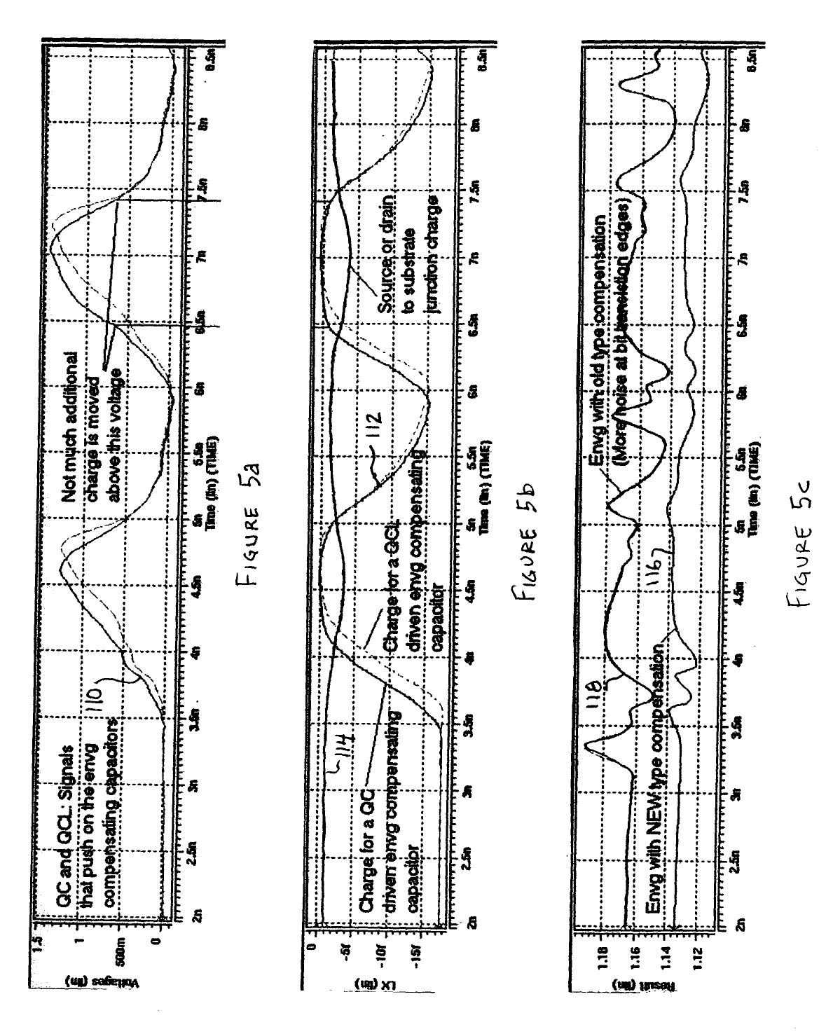

FIG. 5a show an approximated waveform 110 representing signal qc in the circuit of FIG. 4, which is the voltage on compensation node qc 78. As described herein, signal qc 78 is applied to one terminal of compensating capacitance 82, resulting in a charge across capacitance 82 as represented by waveform 112 in FIG. 5b. Waveform 114 in FIG. 5b represents the source or drain to substrate junction charge for capacitor 82.

Waveform 116 in FIG. 5c represents the resultant compensated gate voltage V_{gate} achieved through the practice of the invention, this being the voltage applied to the gate of output transnstor 80. Waveform 116 can be contrasted with waveform 118 in FIG. 5c, which represents the gate voltage in a hypothetical prior art output circuit. In waveform 118, considerable noise in the gate voltage can be observed at bit transition edges relative to the compensated gate voltage of waveform 116.

In some embodiments, the voltage on node qc 78 may not reach an optimum level (i.e., V_{dd}, given that N-channel FET 96 is used for pull-up. In an alternative embodiment, a P-channel FET may be substituted for N-channel FET 96, with its gate being driven by the output of inverter 92, but in such an implementation the signal q tracking might be impaired. In addition, since normal N-channel transistors are used for capacitor 82 (and possibly capacitor 86), the majority of the gate charge is transferred when the source and drains thereof reach about 0.6 V with the gate at about 1.1 V. Thus, it is not necessary for signal qc to reach full V_{dd}; in fact, if it did, power would be wasted, since the junction capacitance is moved as well, as is apparent in FIG. 5b.

In an alternative embodiment, depletion mode devices can be used to implement capacitor 82.

A further potential advantage of the embodiment of the invention shown in FIG. 4 is that fixed capacitor 86 in FIG. 4 is somewhat smaller than fixed capacitor 58 in the embodiment of FIG. 3. Capacitor 86 can be smaller because the active circuitry driving capacitor 82 compensates for the noise on V_{gate} more accurately. Thus, not only does the embodiment of FIG. 4 achieve an even greater smoothing of the V_{gate} voltage, less die area is needed to do so.

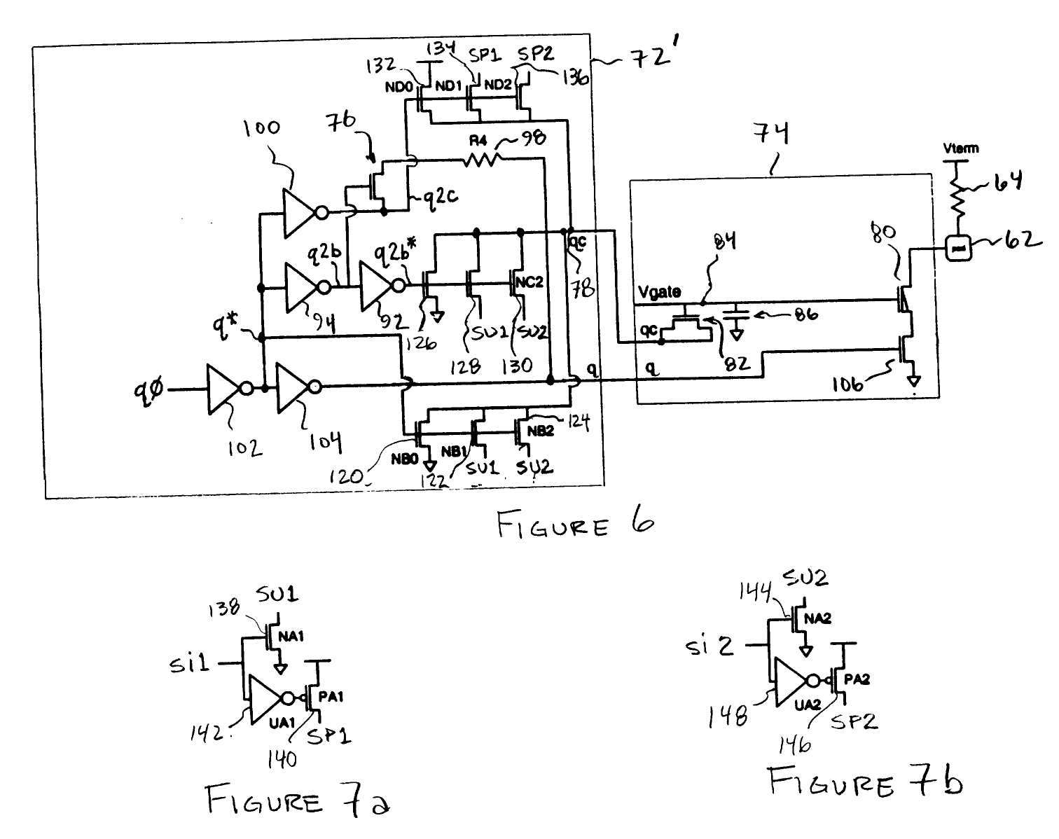

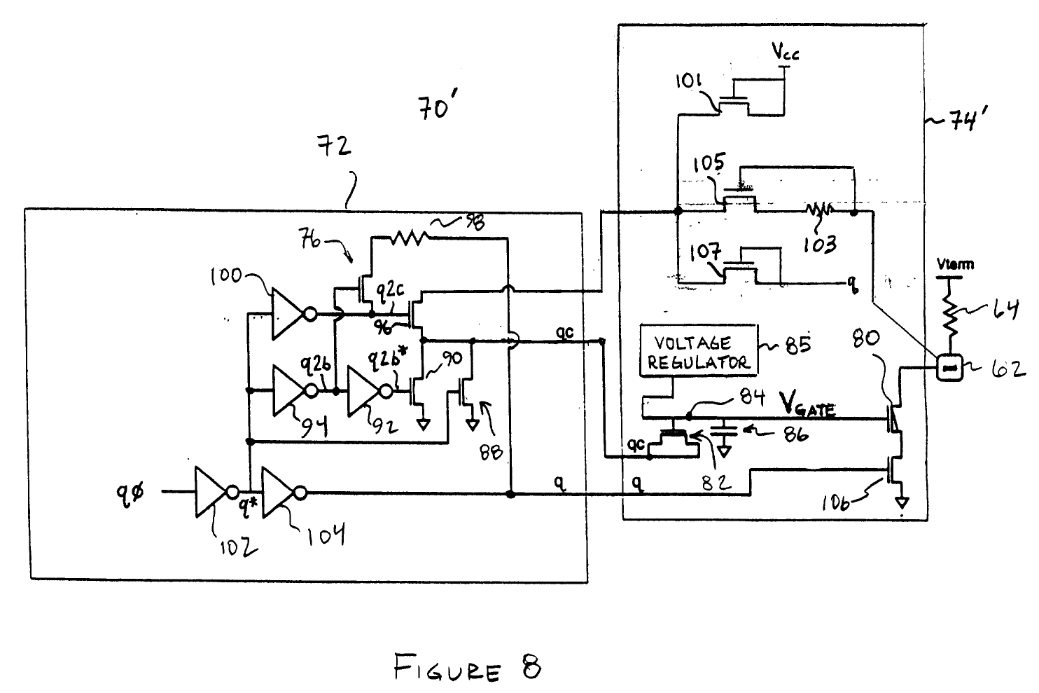

An alternative embodiment, depicted in simple schematic form in FIGS. 6, 7a and 7b is contemplated in which the sizes of the transistors for pulling up and pulling down qc node 78 can be corrected for strength, supply potential level, and temperature. In FIG. 6, those circuit elements which are essentially identical to those in the embodiment of FIG. 4 have retained identical reference numerals.

In the embodiment of FIGS. 6, 7a, and 7b, two inputs, si1 and si2, constitute a two bit code (si1 and si2) representing the relative strengths of n-channel and p-channel devices on the die, which may various based on such factors as transistor strength, temperature, and supply potential. Signals si1 and si2 are generated by circuitry (not shown in the Figures) that compares the relative strengths of n-channel and p-channel devices on the die. Those of ordinary skill in the art will appreciate that the relative strengths of n-channel and p-channel devices on a semiconductor die can vary for a number of reasons, including process variation, temperature, and supply voltage levels, among others. Signals si1 and si2 could be generated based on fuse options, although this would limit the compensating function to process variation alone, as opposed to such real-time variables as temperature or power supply levels. Referring to FIG. 6, transistor 120 (and, as will be hereinafter described, optionally transistors 122, and 124 as well) provides early pull-down to qc node 78 in a manner analogous to transistor 88 in the embodiment of FIG. 4, and transistor 126 (and, optionally, transistors 128, and 130) provides late pull-down to qc node 78 in a manner analogous to transistor 90 in the embodiment of FIG. 4. Transistor 132 (and, optionally, transistors 134, and 136) provides pull-up to qc node 78 in a manner analogous to transistor 96 in the embodiment of FIG. 4.

Referring to FIG. 7a, bit si1 determines whether or not a node designated su1 is coupled to ground potential via an N-channel transistor 138. Bit si1 also determines whether or not a node sp1 is coupled to V_{dd} via a P-channel transistor 140, whose gate is controlled by the output of an inverter 142. Similarly, referring to FIG. 7b, bit si2 determines whether or not a node su2 is grounded, through an N-channel transistor 144, and whether or not a node sp2 is coupled to V_{dd}, via a P-channel transistor 146 whose gate is controlled by the output of an inverter 148.

Referring again to FIG. 6, it is apparent that transistors 134 and 136 are selectively coupled to V_{dd} based upon the state of bits si1 and si2, respectively, owing to the connection of transistor 134 to node sp1 (FIG. 7a) and the connection of transistor 136 to node sp2 (FIG. 7b). Specifically, if bit si1 is 0, the output of inverter 142 is high, turning off transistor 140 such that transistor 134 is decoupled from V_{dd}, whereas if bit si1 is 1, the output of inverter 142 is low, turning on transistor 140 such that transistor 134 is coupled to V_{dd}. Likewise, the coupling of transistor 136 is controlled by the state of bit si2, which controls whether transistor 146 couples transistor 136 to V_{dd}. Thus, depending upon the state of bits si12 and si2, neither, either or both of transistors 134 and 136 can be activated to join transistor 132 in pulling up qc node 78.

Transistors 122 and 124, and transistors 128 and 130, are similarly controlled by the state of bits si1 and si2, owing to the connection of transistors 122 and 128 to node su1 (FIG. 7a) and the connection of transistors 124 and 130 to node su2 (FIG. 7b). For example, when bit si1 is 1, transistor 138 (FIG. 7a) turns on, thereby coupling transistors 122 and 128 to ground, whereas when bit si1 is 0, transistor 138 turns off, decoupling transistors 122 and 128 from ground. Likewise, bit si2 determines whether transistors 124 and 130 are coupled to ground via transistor 144. Thus, depending upon the state of bits si1 and si2, neither, either, or both of transistors 128 and 130 can join transistor 126 delayed pull-down of qc node 78, and neither, either, or both of transistors 122 and 124 can join transistor 120 in early pull-down of qc node 78.

Those of ordinary skill in the art will appreciate that the compensation concept applied in the embodiment of FIGS. 6, 7a, and 7b need not be limited to two bits. This would add more degrees of freedom to achieve further compensation control across various cases.

Turning to FIG. 8, an alternative embodiment 70′ of the invention incorporating a power-saving option is also contemplated wherein charge is taken from the output channel. In the embodiment of FIG. 8, those elements that are substantially identical to elements in the embodiments of FIGS. 4-7 have retained identical reference numerals in FIG. 8 and will not be described in further detail with reference to FIG. 8.

As noted, the embodiment of FIG. 8 incorporates a power-saving option whereby the output channel additionally functions as a supplemental power supply. As noted above, the termination voltage Vₜₑᵣₘ (which may be, for example, 1.8 V) is tied to the output pad 62 via resistance 64. Since pad 62 needs to be pulled down at the same time that transistor 96 needs to draw power, the power requirements are complementary in nature, such that overall system power consumption is reduced as compared with arrangements in which power is drawn straight from V_{CC}.

As shown in FIG. 8, transistor 96 receives power from pad terminal 62 via a resistance 103 and a diode-connected transistor 105. Transistors 101 and 107 work in concert with transistor 105 to ensure that proper levels are achieved at transistor 96. Transistors 101 and 107 are preferably much smaller than transistor 105, such that transistor 105 takes the majority of the loading. Transistors 101 and 107 merely provide additional insurance that the requirements of transistor 96 are supported

From the foregoing detailed description of specific embodiments of the invention, it should be apparent that methods and apparatuses for noise compensation in open-drain output driver circuits has been disclosed. Although specific embodiments of the invention have been disclosed herein in some detail, this has been done solely for the purposes of describing various features and aspects of the invention, and is not intended to be limiting with respect to the scope of the invention. Moreover, it will be apparent to those of ordinary skill in the art that the invention may be practiced in connection with various categories of semiconductor devices having open-drain output circuits. It is contemplated that various substitutions, alterations, and/or modifications, including but not limited to those implementation variations which may have been suggested herein, may be made to the disclosed embodiments without departing from the spirit and scope of the invention as defined by the appended claims, which follow.

What is claimed is:

1. An open-drain output circuit for a semiconductor device, comprising:
an output transistor having a first terminal coupled to an output pad of said semiconductor device, a second terminal selectively coupled to ground potential via a source-to-drain path of a second transistor, and having a gate terminal coupled to a voltage regulator output node and receiving a substantially constant voltage signal therefrom;
an input terminal for receiving an input signal, said input terminal coupled to a gate terminal of said second transistor, and coupled to a gate terminal of a pull-up transistor, said pull-up transistor being coupled between a compensation node and a voltage supply and being responsive to said input signal to selectively pull up the voltage on said compensation node;
at least one inverter receiving said input signal and generating a first complementary input signal;
a first pull-down transistor coupled between said compensation node and ground potential, said first pull-down transistor being responsive to said first complementary input signal applied to its gate terminal to selectively pull down the voltage on said compensation node; and
a capacitance disposed between said compensation node and said voltage regulator output node;
wherein said capacitance couples said voltage on said compensation node to said voltage regulator output node to compensate for fluctuations in said substantially constant voltage signal occurring upon assertion of said input signal.

2. An open-drain output circuit in accordance with claim 1, further comprising:
a second pull-down transistor, receiving a second complementary input signal at its gate and responsive to said second complementary input signal to establish a source-to-drain path between said compensation node and ground potential.

3. An open-drain output circuit in accordance with claim 1, wherein said capacitance comprises a field-effect transistor (FET) configured as a capacitor.

4. An open-drain output circuit in accordance with claim 3, wherein a source terminal and a drain terminal of said FET are coupled to said compensation node and a gate terminal of said FET is coupled to said voltage regulator output node.

5. An open-drain output circuit in accordance with claim 1, further comprising a capacitance coupled between said voltage regulator output node and ground potential.

6. An open-drain output circuit in accordance with claim 2, wherein said input signal passes through first, second, and third inverters, the output of said third inverter comprising said second complementary input signal.

7. An open-drain output circuit in accordance with claim 1, wherein said input signal passes through first and second inverters before being applied to said gate of said pull-up transistor.

8. An open-drain output circuit in accordance with claim 1, wherein said input signal passes through first and second inverters before being applied to said gate of said second transistor.

9. An open-drain output circuit in accordance with claim 1, further comprising a termination resistance coupled between said output pad and a termination voltage source.

10. An open-drain output circuit in accordance with claim 1, further comprising a selective resistive coupling between said input signal and said gate of said pull-up transistor.

11. A method of driving an output signal at an open-drain output of a semiconductor device, comprising:
providing an output transistor having a first terminal coupled to an output pad of said semiconductor device, a second terminal selectively coupled to ground potential via a source-to-drain path of a second transistor, and having a gate terminal coupled to a voltage regulator output node and receiving a substantially constant voltage signal therefrom;
receiving an input signal at an input terminal, said input terminal being coupled to a gate terminal of said second transistor, and coupled to a gate terminal of a pull-up transistor;
disposing said pull-up transistor between a compensation node and a voltage supply and being responsive to said input signal to selectively pull up the voltage on said compensation node;
receiving said input signal at at least one inverter and generating a first complementary input signal;
disposing a first pull-down transistor between said compensation node and ground potential, said first pull-down transistor being responsive to said first complementary input signal applied to its gate terminal to selectively pull down the voltage on said compensation node; and
coupling a capacitance between said compensation node and said voltage regulator output node;
wherein said capacitance couples said voltage on said compensation node to said voltage regulator output node to compensate for fluctuations in said substantially constant voltage signal occurring upon assertion of said input signal.

12. A method in accordance with claim 11, further comprising:
receiving a second complementary input signal at a gate of a second pull-down transistor, said second pull-down transistor being responsive to said second complementary input signal to establish a source-to-drain path between said compensation node and ground potential.

13. A method in accordance with claim 11, further comprising configuring a field-effect transistor (FET) as a capacitor to provide said capacitance.

14. An open-drain output circuit in accordance with claim 13, wherein said step of configuring said FET as a capacitor comprising coupling said a source terminal and a drain terminal of said FET to said compensation node and coupling a gate terminal of said FET to said voltage regulator output node.

15. A method in accordance with claim 11, further comprising disposing a capacitance between said voltage regulator output node and ground potential.

16. A method in accordance with claim 12, further comprising applying said input signal to first, second, and third series-connected inverters to produce said second complementary input signal.

17. A method in accordance with claim 11, further comprising applying said input signal to first and second series-connected inverters and applying the output of said second inverter to said gate of said pull-up transistor.

18. A method in accordance with claim 11, further comprising applying said input signal to first and second series-connected inverters and applying the output of said second inverter to said gate of said second transistor.

19. A method in accordance with claim 11, further comprising providing a termination resistance coupled between said output pad and a termination voltage source.

20. A method in accordance with claim 11, further comprising providing a selective resistive coupling between said input signal and said gate of said pull-up transistor.

21. A semiconductor memory device having at least one open-drain output, comprising:
an array of rows and columns of memory cells each adapted to store a bit of data;
address decoding circuitry for selecting a memory cell from which a bit of data is read;
an output transistor having a first terminal coupled to an output pad of said semiconductor device, a second terminal selectively coupled to ground potential via a source-to-drain path of a second transistor, and having a gate terminal coupled to a voltage regulator output node and receiving a substantially constant voltage signal therefrom;
an input terminal for receiving an input signal corresponding to said bit of data from said selected memory cell, said input terminal coupled to a gate terminal of said second transistor, and coupled to a gate terminal of a pull-up transistor, said pull-up transistor being coupled between a compensation node and a voltage supply and being responsive to said input signal to selectively pull up the voltage on said compensation node;
at least one inverter receiving said input signal and generating a first complementary input signal;
a first pull-down transistor coupled between said compensation node and ground potential, said first pull-down transistor being responsive to said first complementary input signal applied to its gate terminal to selectively pull down the voltage on said compensation node; and
a capacitance disposed between said compensation node and said voltage regulator output node;
wherein said capacitance couples said voltage on said compensation node to said voltage regulator output node to compensate for fluctuations in said substantially constant voltage signal occurring upon assertion of said input signal.

22. A semiconductor memory device in accordance with claim 21, further comprising: a second pull-down transistor, receiving a second complementary input signal at its gate and responsive to said second complementary input signal to establish a source-to-drain path between said compensation node and ground potential.

23. A semiconductor memory device in accordance with claim 21, wherein said capacitance comprises a field-effect transistor (FET) configured as a capacitor.

24. A semiconductor memory device in accordance with claim 23, wherein a source terminal and a drain terminal of said FET are coupled to said compensation node and a gate terminal of said FET is coupled to said voltage regulator output node.

25. A semiconductor memory device in accordance with claim 21, further comprising a capacitance coupled between said voltage regulator output node and ground potential.

26. A semiconductor memory device in accordance with claim 22, wherein said input signal passes through first, second, and third inverters, the output of said third inverter comprising said second complementary input signal.

27. A semiconductor memory device in accordance with claim 21, wherein said input signal passes through first and second inverters before being applied to said gate of said pull-up transistor.

28. A semiconductor memory device in accordance with claim 21, wherein said input signal passes through first and second inverters before being applied to said gate of said second transistor.

29. A semiconductor memory device in accordance with claim 21, further comprising a termination resistance coupled between said output pad and a termination voltage source.

30. A semiconductor memory device in accordance with claim 21, further comprising a selective resistive coupling between said input signal and said gate of said pull-up transistor.

31. A semiconductor memory device in accordance with claim 21, wherein said memory device is a dynamic random access memory.

32. An open-drain output circuit for a semiconductor device, comprising:
an output transistor having a first terminal coupled to an output pad of said semiconductor device, a second terminal selectively coupled to ground potential via a source-to-drain path of a second transistor, and having a gate terminal coupled to a voltage regulator output node and receiving a substantially constant voltage signal therefrom;
an input terminal for receiving an input signal, said input terminal coupled to a gate terminal of said second transistor, and coupled to a gate terminal of a plurality of pull-up transistors, a first of said plurality of pull-up transistors being coupled between a compensation node and a voltage supply and being responsive to said input signal to selectively pull up the voltage on said compensation node, and at least a second one of said plurality of pull-up transistors being selectively coupled between said compensation node and a voltage supply;
at least one inverter receiving said input signal and generating a first complementary input signal;
a first pull-down transistor coupled between said compensation node and ground potential, said first pull-down transistor being responsive to said first complementary input signal applied to its gate terminal to selectively pull down the voltage on said compensation node;
at least a second pull-down transistor selectively coupled between said compensation node and ground potential;
a capacitance disposed between said compensation node and said voltage regulator output node;
a first correction circuit coupled to said voltage supply and said at least a second one of said plurality of pull-up transistors, said first correction circuit being responsive to at least one code bit to selectively couple said at least a second one of said plurality of pull-up transistors to said voltage supply, such that said at least a second one of said plurality of pull-up transistors is responsive to said input signal to selectively pull up the voltage on said compensation node; and
a second correction circuit coupled to ground potential and to said at least a second pull-down transistor, said second correction circuit being responsive to said at least one code bit to selectively couple said at least a second one of said plurality of pull-down transistors to said voltage supply, such that said at least a second one of said plurality of pull-down transistors is responsive to said input signal to selectively pull down the voltage on said compensation node;
wherein said capacitance couples said voltage on said compensation node to said voltage regulator output node to compensate for fluctuations in said substantially constant voltage signal occurring upon assertion of said input signal.

33. An open-drain driver circuit in accordance with claim 32, wherein said plurality of pull-up transistors comprises three pull-up transistors and said at least a second one of said plurality of pull-up transistors comprises two pull-up transistors.

34. An open-drain driver circuit in accordance with claim 33, wherein said plurality of pull-down transistors comprises three pull-down transistors and said at least a second one of said plurality of pull-up transistors comprises two pull-down transistors.

35. An open-drain output circuit in accordance with claim 32, further comprising:
a second plurality of pull-down transistors, each receiving a second complementary input signal at its gate;
wherein a first one of said second plurality of pull-down transistors being responsive to said second complementary input signal to establish a source-to-drain path between said compensation node and ground potential
and wherein at least a second one of said second plurality of pull-down transistors being coupled to said compensation node and to said second correction circuit;
and wherein said second correction circuit is responsive to said second code bit to couple said at least a second one of said second plurality of pull-down transistors to ground potential

36. An open-drain output circuit in accordance with claim 32, wherein said capacitance comprises a field-effect transistor (FET) configured as a capacitor.

37. An open-drain output circuit in accordance with claim 36, wherein a source terminal and a drain terminal of said FET are coupled to said compensation node and a gate terminal of said FET is coupled to said voltage regulator output node.

38. An open-drain output circuit in accordance with claim 32, further comprising a capacitance coupled between said voltage regulator output node and ground potential.

39. An open-drain output circuit in accordance with claim 33, wherein said input signal passes through first, second, and third inverters, the output of said third inverter comprising said second complementary input signal.

40. An open-drain output circuit in accordance with claim 32, wherein said input signal passes through first and second inverters before being applied to said gate of said pull-up transistor.

41. An open-drain output circuit in accordance with claim 32, wherein said input signal passes through first and second inverters before being applied to said gate of said second transistor.

42. An open-drain output circuit in accordance with claim 32, further comprising a termination resistance coupled between said output pad and a termination voltage source.

43. An open-drain output circuit in accordance with claim 32, further comprising a selective resistive coupling between said input signal and said gate of said pull-up transistor.
